(19) United States
(12) Patent Application Publication
(10) Pub. No.: US 2006/0115909 A1
(43) Pub. Date: Jun. 1, 2006

(54) Method for manufacturing a resistively switching memory cell, manufactured memory cell, and memory device based thereon

(75) Inventor: Thomas Happ, Tarrytown, NY (US)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/270,835

(22) Filed: Nov. 10, 2005

(30) Foreign Application Priority Data
Nov. 11, 2004 (DE) 10 2004 054 558.8

(51) Int. Cl. H01L 21/00

(52) U.S. Cl. 438/3

(57) ABSTRACT

The invention relates to a method for manufacturing at least one resistively switching memory cell, in particular a phase change memory cell, said method comprising at least the steps of (a) structuring a hardmask applied above a layer and (b) etching back at least part of the structured hardmask, in particular by isotropic etching.

The invention relates to a method for manufacturing a resistively switching memory cell, in particular a phase change memory cell, to a corresponding memory cell, and to a memory device comprising at least one memory cell.

In the case of conventional memory devices, in particular conventional semiconductor memory devices, one differentiates between so-called functional memory devices (e.g. PLAs, PALs, etc.), and so-called table memory devices, e.g. ROM devices (ROM=Read Only Memory—in particular PROMS, EPROMs, EEPROMs, flash memories, etc.), and RAM devices (RAM=Random Access Memory or read-write memory, e.g. DRAMs and SRAMs).

A RAM device is a memory for storing data under a predetermined address and for reading out the data under this address later.

In the case of SRAMs (SRAM=Static Random Access Memory), the individual memory cells consist e.g. of few, for instance 6, transistors, and in the case of so-called DRAMs (DRAM=Dynamic Random Access Memory) in general only of one single, correspondingly controlled capacitive element (e.g. the gate-source capacitor of a MOSFET) with the capacitance of which one bit each can be stored as charge.

This charge, however, remains for a short time only. Therefore, a so-called “refresh” must be performed regularly, e.g. approximately every 64 ms.

In contrast to that, no “refresh” has to be performed in the case of SRAMs, i.e. the data stored in the memory cell remain stored as long as an appropriate supply voltage is fed to the SRAM.

In the case of non-volatile memory devices (NVMs), e.g. EPROMs, EEPROMs, and flash memories, the stored data remain, however, stored even when the supply voltage is switched off.

Furthermore, so-called “resistive” or “resistively switching” memory devices have also become known recently, e.g. so-called Phase Change Memories (“PCRAMS”).

In the case of “resistive” or “resistively switching” memory devices, an “active” or “switching active” material—which is, for instance, positioned between two appropriate electrodes (i.e. an anode and a cathode)—is placed, by appropriate switching processes, in a more or less conductive state (wherein e.g. the more conductive state corresponds to a stored, logic “One”, and the less conductive state to a stored, logic “Zero”, or vice versa). This may, for instance, correspond to the logic arrangement of a bit.

In the case of phase change memories (PCRAMs), for instance, an appropriate chalcogenide compound may be used as a “switching active” material that is positioned between two corresponding electrodes (e.g. a Ge—Sb—Te (“GST”) or an Ag—In—Sb—Te compound).

The chalcogenide compound material is adapted to be placed in an amorphous, i.e. a relatively weakly conductive, or a crystalline, i.e. a relatively strongly conductive state by appropriate switching processes (wherein e.g. the relatively strongly conductive state may correspond to a stored, logic “One”, and the relatively weakly conductive state may correspond to a stored, logic “Zero”, or vice versa).

Phase change memory cells are, for instance, known from G. Wicker, “Nonvolatile, High Density, High Performance Phase Change Memory”, SPIE Conference on Electronics and Structures for MEMS, Vol. 3891, Queensland, 2, 1999, and e.g. from Y. N. Hwang et al., “Completely CMOS Compatible Phase Change Nonvolatile RAM Using NMOS Cell Transistors”, IEEE Proceedings of the Nonvolatile Semiconductor Memory Workshop, Monterey, 91, 2003, S. Lai et al., “OUM-a 180 nm nonvolatile memory cell element technology for stand alone and embedded applications”, IEDM 2001, etc.

In order to achieve, with a corresponding memory cell, a change from an amorphous, i.e. a relatively weakly conductive state of the switching active material, to a crystalline, i.e. a relatively strongly conductive state, an appropriate heating current pulse or heating voltage pulse, respectively, can be applied at the electrodes, said heating pulse resulting in that the switching active material is heated beyond the crystallization temperature and crystallizes (“writing process”).

Vice versa, a change of state of the switching active material from a crystalline, i.e. a relatively strongly conductive state, to an amorphous, i.e. a relatively weakly conductive state, may, for instance, be achieved in that—again by means of an appropriate heating current pulse or heating voltage pulse, respectively—the switching active material is heated beyond the melting temperature and is subsequently “quenched” to an amorphous state by quick cooling (“deleting process”).

To achieve a correspondingly quick heating of the switching active material beyond the crystallization or melting temperature, respectively, relatively high currents may be necessary, which may result in correspondingly high power consumption.

Furthermore, the consequence of high heating currents may be that the corresponding cell can no longer be controlled by an individual transistor with a correspondingly small structure size, which may result in a corresponding—possibly strongly reduced—compactness of the respective memory device.

So far, one has primarily been trying to restrict the programmed volume by a reduction of the contacting face and to thus reduce the required currents. Previous concepts are inter alia described in: S. Lai, T. Lowrey, “OUM-a 180 nm nonvolatile memory cell element technology for stand alone and embedded applications”, IEDM 2001; in: J. Rodgers et al., “Demonstration of Chalcogenide Based Non Volatile Memory”, MAPLD; in: Y. H. Ha, J. H. Yi, H. Horii et al., “An edge contact type cell for phase change RAM featuring very low power consumption”, VSLI, 2003; and in: H. Horii, J. H. Yi et al., “A novel cell technology using N-doped GeSbTe films for phase change RAM”, IEDM 2003.

From Y. N. Hwang et al., “Writing current reduction for high density phase change RAM”, IEDM 2003, it is known that, for achieving low reset currents, a good definition and restriction of the current path is also desirable in addition to this reduction of the switching volume.

Apart from the low reset current, a reliable and reproducible producibility with minor fluctuations in the electric parameters is a further criterion for a successful PCRAM cell, which is no longer achieved with the hitherto described approaches for very small critical dimensions of e.g. 40 nm, cf. e.g. Y. N. Hwang, J. S. Hong et al., “Full integration and reliability evaluation of phase-change RAM”, VSLI 2003.

It is an object of the invention to provide a method for the precise, well reproducible manufacturing of a compact, current path restricting, resistively switching memory cell with minor fluctuations, a corresponding memory cell, and a memory device based thereon.

This is achieved by an invention according to claims 1, 13, and 19. Advantageous further developments of the invention are indicated in the subclaims.

In accordance with a first basic idea of the invention, there is provided a manufacturing method for a resistively switching memory cell, in particular a phase change memory cell, and a memory device based thereon, in which a structurable layer (in the following called hardmask) is positioned above at least one further layer, e.g. was applied there in a previous step. The hardmask is structured, this resulting in a lithographic etchmask. In a further step, the hardmask is etched back at least in a structured partial region. By etching back, the dimensions of the lithographic etchmask are reduced and a “sublithographic” etchmask of outstanding precision is the result, which, moreover, is good to reproduce. Thus, the dimensions of further layers positioned below the hardmask may also be reduced, in particular the face or the volume, respectively, of a switching active material or element—and thus the current or the voltage, respectively, required for switching. The result of this alone is a current path restricting effect.

By means of the sublithographic etchmask, correspondingly small switching active elements and thus also devices of small dimensions can be realized, e.g. small 1T1R cells, e.g. with a cell face of 5-8F². Transistors with gate lengths of 45 nm can, for instance, be manufactured with very good statistics. Thus, highly integrated 1T1R-PCRAM memory cells or memory devices, respectively, with cell fields of high density can, for instance, be manufactured. The corresponding current reduction, e.g. below a current of 50 μA to 100 μA—depending on the generation of technology—is advantageous from an energetic view in particular for the parallel programming of memory cells.

It is favorable if the switching active layer comprises chalcogenide compounds (e.g. a Ge—Sb—Te (“GST”) or an Ag—In—Sb—Te compound), preferably sputtered.

Such a reduction of dimension cannot be achieved for resistively switching memory devices, in particular PCRAMs, with prior art.

A structuring of the hardmask by conventional—and thus i.a. inexpensive—lithographic methods is preferred. The structuring comprises all the process steps necessary to this end, i.e., for instance, also preparatory steps such as the cleaning or preparing of surfaces if necessary. Thus, the hardmask may be deglazed, e.g. by dilute hydrofluoric acid (“dilute HF deglaze”) if necessary.

The etching back of the structured hardmask preferably takes place by isotropic etching, in particular isotropic wet chemical etching.

For manufacturing cell fields with a plurality of individual memory cells, a method is preferred in which the hardmask is structured in the form of an ellipse, i.e. in particular in the form of a circle or a cylinder. Other forms, e.g. a linear or—largely—rectangular structure are, however, also possible.

The material of the hardmask advantageously comprises at least Si3N4 or SiN.

For protection of layers positioned therebelow, the hardmask may also consist of a multi-layer composition, for instance, of a dielectric two-layer composition, in particular of SiN on SiO₂. The top layer may be used as a sacrifice layer during the “pull back” step for size reduction while the bottom layer protects the electrode as a protective layer during wet etching and is also etched through during dry etching. Both layers may, however, also be considered as individual layers with different functionalities.

Further preferred is a method in which the etching back of the at least one part of the structured hardmask—in particular a hardmask with Si₃N₄— takes place by means of hot H₃PO₄, in particular by H₃PO₄ in a temperature range of more than 60° C., in particular around 65° C. A lower temperature is, of course, also possible. The choice of temperature depends inter alia on the desired etching rate since, at a higher temperature, the etching process is usually performed more quickly. In the case of other materials of the hardmask and/or other materials of the hardmask and the layer(s) therebelow, other etches may also be used. Hot H₃PO₄ has the advantage that it etches isotropically and, by a suitable choice of temperature, also sufficiently slowly for a precise etching. Etching times of approx. 10 min. are, for instance, advantageous.

Advantageous is further a method in which at least one further layer that is positioned below the structured, etched-back hardmask is etched back, in particular by dry etching. There may be as many layers as desired with different functionalities such as switching activity, contacting, chemical/mechanical protection, etc.

It is of particular advantage if at least one further layer that is positioned below the structured, etched-back hardmask comprises the switching active layer or even is the switching active layer. By this, the small sublithographic dimension of the hardmask can be transferred to a correspondingly small volume of the switching cell.

Moreover, a method is favorable in which at least one further layer that is positioned below the structured, etched-back hardmask comprises a top electrode since this enables a manufacturing of contacts that is simple with respect to process technology. It is also favorable if at least one further layer that is positioned below the structured, etched-back hardmask comprises a bottom electrode or part of a bottom electrode, respectively, for instance an intermediate electrode.

From a process-technological view, a method is also advantageous in which, when a top electrode layer and a switching active layer are present, both layers can be etched back, if possible, but not necessarily, in one step. Particularly favorable is the etching back of the top electrode layer, followed by an etching back of the switching active layer, and possibly of the bottom electrode.

The applying, structuring and etching back of the hardmask and the etching back of at least one further layer therebelow can also be performed several times.

A method which provides, after the etching back of the switching active layer has been performed, the step of depositing of an insulation layer of electrically insulating material is also favorable.

This is especially favorable if the deposition of the insulation layer (in the following called “top insulation layer” for the sake of simplification) is performed such that the switching active layer is completely embedded laterally into the top insulation layer. Due to the further focused current flow reached by the embedding of the switching active material into the insulation material (and thus the reduction or prevention, respectively, of parasitic currents occurring outside the melting or crystallization range of the switching active material), the switching active material can be heated beyond the crystallization or melting temperature with partially distinctly lower heating currents than are described in prior art. If, at the same time, the switching active material is enclosed from the top by the top electrode layer, a favorable contamination-safe CMOS integration is also enabled.

For easy contacting, in particular top contacting, the surface comprising the top insulation layer is advantageously removed flatly (e.g. by polishing, e.g. by a CMP method), favorably such that the switching active layer is contactable. If a top electrode layer is present, this can, for instance, be achieved by a removal up to this layer.

The method yields a memory cell with at least partially sublithographic dimensions. In particular, a memory cell can be manufactured in which a sublithographically dimensioned switching active layer or a sublithographically dimensioned switching active element, respectively, is present. Thus, e.g. the above-mentioned 1T1R cells having small space requirement can be manufactured.

A memory cell can in particular be manufactured in which the switching active layer is completely embedded laterally into an insulation layer, in particular if the material of the insulation layer comprises at least SiO₂, SiN and/or some other suitable insulator material such as low-1-dielectrics.

Advantageous is a memory cell in which the electrode material comprises a titanium compound, in particular TiN, but also TiSiN, TiAlN, TiW, TaN, TaAlN, or of TaSiN or tungsten. Particularly favorable is the combination of one electrode with TiN (in particular the top electrode) and the other electrode of tungsten (in particular the bottom electrode).

The switching active material preferably comprises a Ge—Sb—Te (“GST”) or an Ag—In—Sb—Te compound, in particular sputtered GST.

Also claimed is a memory device comprising at least one—preferably a cell field comprising a plurality—of the above-described inventive memory cells, in particular with at least one further contacting, e.g. a (metal) contact electrode in connection to a top electrode.

In the following, the invention will be explained in more detail by means of several embodiments and the enclosed drawing. The drawing shows:

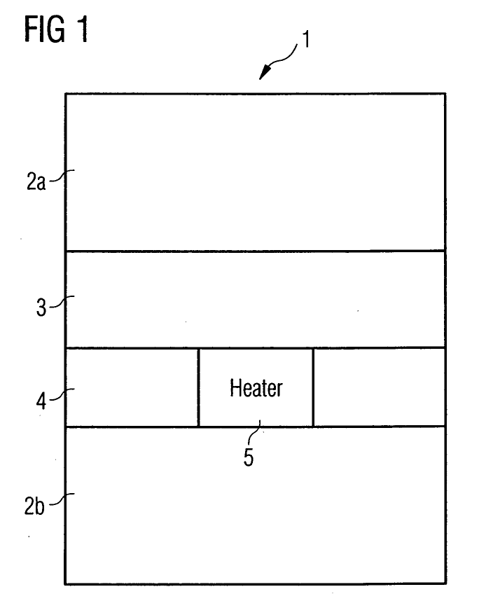

FIG. 1 a schematic representation of the structure of a resistively switching memory cell according to prior art;

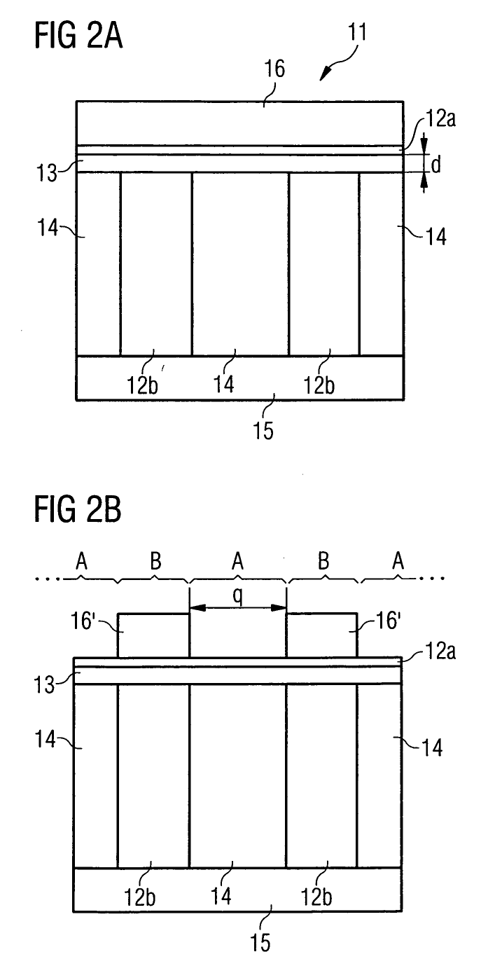

FIG. 2a a schematic representation of resistively switching memory cells according to an embodiment of the present invention at a first phase during the manufacturing of the memory cells;

FIG. 2b a schematic representation of the resistively switching memory cell illustrated in FIG. 2a at a second phase during the manufacturing of the memory cells;

FIG. 2c a schematic representation of the resistively switching memory cells illustrated in FIGS. 2a and 2b at a third phase during the manufacturing of the memory cells;

FIG. 2d a schematic representation of the resistively switching memory cells illustrated in FIGS. 2a to 2c at a fourth phase during the manufacturing of the memory cells;

FIG. 2e a schematic representation of the resistively switching memory cells illustrated in FIGS. 2a to 2d at a fifth phase during the manufacturing of the memory cells;

FIG. 2f a schematic representation of the resistively switching memory cells illustrated in FIGS. 2a to 2e at a sixth phase during the manufacturing of the memory cells;

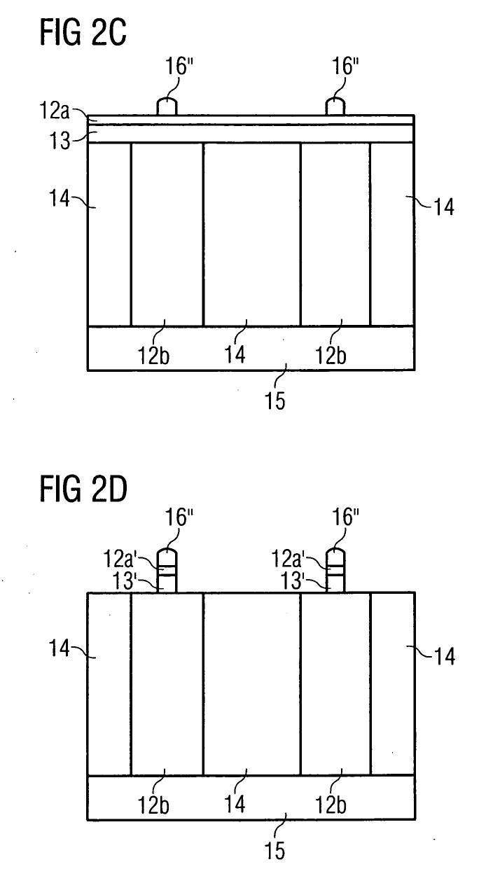

FIG. 3 a schematic representation of the finished memory cell; and

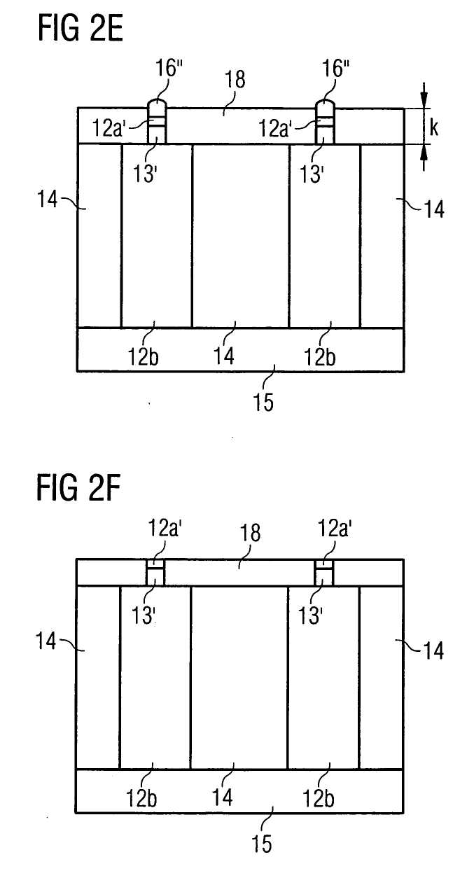

FIG. 4 a schematic representation of resistively switching memory cells according to a further, alternative embodiment of the present invention at a first phase during the manufacturing of the memory cells corresponding to the phase illustrated in FIG. 2a; and

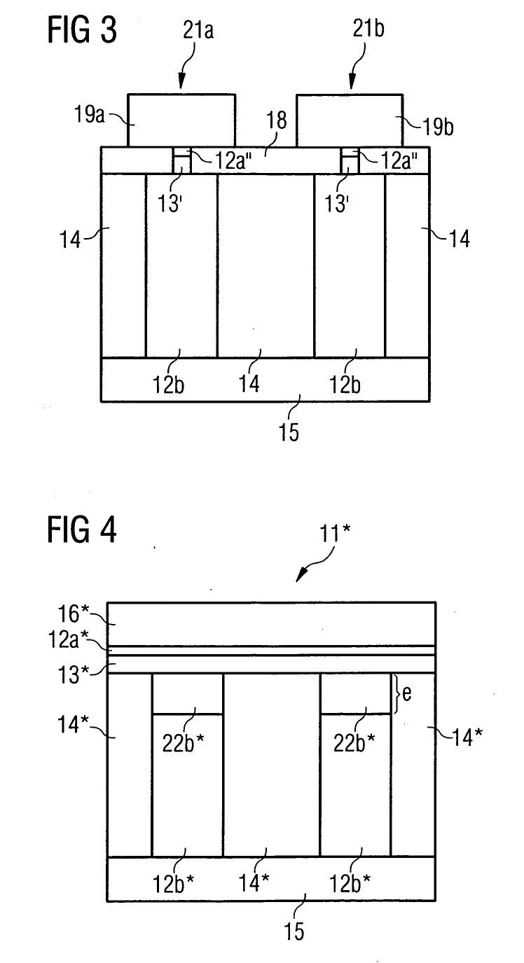

FIG. 5 a schematic representation of the resistively switching memory cells according to a further, alternative embodiment of the present invention at a phase during the manufacturing of the memory cells corresponding to the phase illustrated in FIG. 2e; and

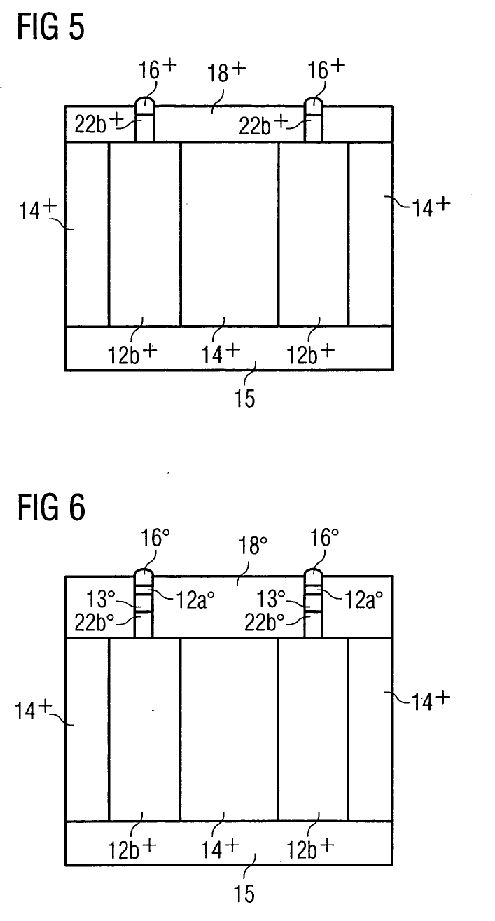

FIG. 6 a schematic representation of the manufacturing of resistively switching memory cells according to a further, alternative embodiment of the present invention at a phase corresponding to the phase illustrated in FIG. 2e.

FIG. 1 shows—purely schematically and for the sake of example—the structure of a resistively switching memory cell 1 (here: of a phase change memory cell 1) according to prior art.

It comprises two appropriate, here: metal electrodes 2a, 2b (i.e. one anode and one cathode) with a corresponding, switching active material layer 3 positioned therebetween, said switching active material layer 3 being adapted to be positioned in a more or less conductive state by appropriate switching processes (wherein e.g. the more conductive state corresponds to a stored, logic “One” and the less conductive state to a stored, logic “Zero”, or vice versa).

With the above-mentioned phase change memory cell 1, an appropriate chalcogenide compound (e.g. a Ge—Sb—Te or an Ag—In—Sb—Te compound) may, for instance, be used as “switching active” material.

The chalcogenide compound material is adapted to be placed in an amorphous, i.e. a relatively weakly conductive, or a crystalline, i.e. a relatively strongly conductive state by means of appropriate switching processes (wherein e.g. the relatively strongly conductive state may correspond to a stored, logic “One” and the relatively weakly conductive state to a stored logic “Zero”, or vice versa).

Phase change memory cells are, for instance, known from G. Wicker, Nonvolatile, High Density, High Performance Phase Change Memory, SPIE Conference on Electronics and Structures for MEMS, Vol. 3891, Queensland, 2, 1999, and e.g. from Y. N. Hwang et al., Completely CMOS Compatible Phase Change Nonvolatile RAM Using NMOS Cell Transistors, IEEE Proceedings of the Nonvolatile Semiconductor Memory Workshop, Monterey, 91, 2003, S. Lai et al., OUM-a 180 nm nonvolatile memory cell element technology for stand alone and embedded applications, IEDM 2001, etc.

As results further from FIG. 1, phase change memory cells 1 may—optionally—be provided an appropriate heating material layer 5—which has, for instance, a relatively high resistance—below the switching active material layer 3 and above the bottom electrode 2b, said heating material layer 5 being surrounded by an appropriate insulation layer 4.

In order to achieve, with the memory cell 1, a change from an amorphous, i.e. a relatively weakly conductive state of the “active” material, to a crystalline, i.e. relatively strongly conductive state, an appropriate heating current pulse can be applied at the electrodes, said heating current pulse resulting in that the heating material layer 5 and regions of the switching active material layer 3 adjacent thereto are correspondingly heated beyond the crystallization temperature of the switching active material, which results in a crystallization of the corresponding regions of the switching active material layer 3 (“writing process”).

Vice versa, a change of state of the corresponding regions of the switching active material layer 3 from a crystalline, i.e. a relatively strongly conductive state, to an amorphous, i.e. a relatively weakly conductive state, may, for instance, be achieved by—again by applying an appropriate heating current pulse at the electrodes 2a, 2b and the resulting heating up of the heating material layer 5 and of corresponding regions of the switching active material layer 3—the corresponding regions of the switching active material layer 3 being heated beyond the melting temperature and being subsequently “quenched” to a crystalline state by quick cooling (“deleting process”).

To achieve a correspondingly quick heating of the corresponding regions of the switching active material layer 3 beyond the crystallization or melting temperature, respectively, relatively high currents may be necessary.

FIG. 2a is a schematic representation of resistively switching memory cells 11 according to an embodiment of the present invention at a first phase during the manufacturing of the memory cells 11.

The memory cells 11 may in particular be phase change memory cells 11 (in particular for PCRAMs), as will be explained in more detail in the following.

As results from FIG. 2a, an appropriate “switching active” layer 13 comprising a switching active material is positioned between two corresponding electrode (layers) or contacts 12a, 12b (i.e. one anode and one cathode) that have been manufactured or are to be manufactured, respectively, as will be explained in more detail in the following.

The switching active layer 13 is—in the finished state of the cells 11 (and as will be explained in more detail further below)—adapted to be placed in a more or less conductive state by means of appropriate switching processes (in particular in an amorphous, i.e. a relatively weakly conductive, or a crystalline, i.e. a relatively strongly conductive state, wherein e.g. the more conductive state corresponds to a stored, logic “One” and the less conductive state to a stored, logic “Zero”, or vice versa).

As a switching active material for the above-mentioned material layer 13, an appropriate chalcogenide compound may, for instance, be used (e.g. a Ge—Sb—Te or an Ag—In—Sb—Te compound, etc.), or any other suitable phase change material.

As a material for the top electrode layer 12a or the top contact, respectively, a titanium compound such as TiN, TiSiN, TiAlN, TaSiN, TaN, TiAlN, or TiW, etc., is preferably used. Tungsten or any other suitable electrode material is, however, also suitable.

The bottom electrode or the bottom contact 12b, respectively, is preferably manufactured of tungsten, may, however, also be manufactured of any other suitable electrode material.

As results in particular from the representation according to FIG. 3, each of the bottom contacts 12b is—in the finished state of the memory cells 11—assigned to a respective individual memory cell 21a, 21b.

The bottom contacts 12b of the memory cells 11 are separated from each other by a corresponding (bottom) insulation layer 14 positioned between the bottom contacts 12b (and surrounding the bottom contacts 12b laterally).

The bottom insulation layer 14 may, for instance, consist of SiO₂ or of any other suitable insulation material.

Again referring to FIG. 2a, a substrate, here in the form of a substrate layer 15 that may, for instance, be manufactured of silicon, is positioned below the memory cells 11 (or below the bottom contacts 12b and the bottom insulation layer 14, respectively (directly adjacent to the bottom limiting regions of the bottom contacts 12b and the insulation layer 14—being in the same plane).

In the substrate layer 15, appropriate switching elements, in particular transistors—that control the finished individual memory cells 21a, 21b, and in particular provide the heating currents required for writing and deleting the individual memory cells 21a, 21b—may be arranged, and e.g. appropriate sense amplifiers that read out the data stored in the individual memory cells 21a, 21b, etc.

As will be explained in more detail further below, relatively low heating currents may be used with the memory cells 21a, 21b according to FIGS. 2a to 4, in particular heating currents that are smaller than e.g. 130 μA or e.g. 100 μA, in particular smaller than 80 μA or 60 μA, etc., so that a corresponding individual memory cell 21a, 21b can be controlled by one single, assigned switching element that provides the corresponding heating current (and comprises e.g. only one single or two cooperating, oppositely inverse transistors, or a correspondingly switched individual diode) (in particular by a transistor, or a diode, or by transistors, respectively, with a correspondingly small (minimum) structure size).

As results further from FIG. 2a (at the phase during the manufacturing of the memory cells 11 illustrated there), the switching active layer 13 that has a constant thickness d of e.g. <150 nm, in particular e.g. <100 nm (or e.g. <60 nm or <30 nm) extends first of all in the form of a continuous, horizontal, plane layer above a plurality of bottom electrodes or bottom contacts 12b of the memory cells 11 which are positioned side by side (and are assigned to different individual memory cells 21a, 21 to be produced), and above the above-mentioned bottom insulation layer 14.

As results also from FIG. 2a, the top electrode layer that is provided above the switching active material layer 13 and is used for the manufacturing of the top electrodes or of the top contacts, respectively, extends—correspondingly—first of all (at the phase illustrated in FIG. 2a) also in the form of a continuous, horizontal, plane layer above the above-mentioned plurality of adjacent bottom electrodes or bottom contacts 12b, respectively (assigned to different individual memory cells 21a, 21b to be produced) of the memory cells 11.

Above the top electrode layer 12a, a further layer is provided, as results from FIG. 2a. This layer is referred to as hardmask 16 in the following. The hardmask 16 preferably consists of SiN or Si₃N₄, may, however, also consist of some other suitable material such as SiO₂ or of a layer composition, e.g. a dielectric layer composition of—e.g.—SiN on.

SiO2, wherein the top layer is used as a sacrifice layer during the “pull-back” step for size reduction while the bottom layer protects the electrode during wet etching as a protective layer and is also etched through during dry etching.

As results from FIG. 2a, the bottom limiting areas of regions of the switching active layer 13 positioned above the bottom insulation layer 14 are directly adjacent to corresponding top limiting areas of the bottom insulation layer 14.

Furthermore—as is illustrated in FIG. 2a—the bottom limiting areas of regions of the switching active layer 13 positioned above the bottom electrodes or bottom contacts 12b, respectively, of the memory cells 11, may be directly adjacent to corresponding top limiting areas of the contacts 12b (the top limiting areas of the contacts 12b and of the bottom insulation layer 14 will then be in one and the same plane).

In an alternative embodiment of the invention which is illustrated in FIG. 4, corresponding (intermediate) electrodes 22b—may be provided, in memory cells 11—that are otherwise structured and manufactured correspondingly similar to the memory cells 11 illustrated in FIGS. 2a to 2f, between the switching active layer 13* and the contacts 12b* that consist e.g. of tungsten, as has been explained above.

The intermediate electrodes 22b* that are positioned between the switching active layer 13* and the bottom contacts 12b* (and that are also surrounded by an appropriate bottom insulation layer 14*) may, for instance, be manufactured of a specific material, e.g.—corresponding to the top electrode 12a*—of TiN, or e.g. of TiSiN, TIAIN, TaSiN, TaAlN, or TaN, etc.

As results from FIG. 4, then—other than with the embodiment illustrated in FIGS. 2a to 2f-corresponding bottom limiting areas of regions of the switching active layer 13* (that are positioned above the bottom contacts 12b* of the memory cells 11*) may be adjacent to corresponding top limiting areas of the intermediate electrodes 22b* (and corresponding bottom limiting areas of the intermediate electrodes 22b* to corresponding top limiting areas of the bottom (tungsten) contacts 12b*).

As results also from FIG. 4, in the embodiment illustrated there, the top limiting areas of the intermediate electrodes 22b* and of the bottom insulation layer 14* are in one and the same plane or are part of a planar layer stack.

The intermediate electrodes 22b* may, for instance, be manufactured in that bottom (tungsten) contacts 12b*—that extend first of all correspondingly similar as with the embodiment illustrated in FIG. 2a to the top to the same extent as the bottom insulation layer 14*—are correspondingly etched back (selectively) to some extent—corresponding to the later thickness e of the intermediate electrodes 22b*—(with the surrounding bottom insulation layer 14* being correspondingly left).

Subsequently, an appropriate material layer consisting of the material desired for the intermediate electrodes 22b* can be deposited above the—etched-back—bottom (tungsten) contacts 12b* (and thus also above the insulation layer 12*).

This material layer is correspondingly polished back—planarly—up to the height of the top limiting area of the bottom insulation layer 14* (e.g. by means of an appropriate CMP method (CMP=Chemical Mechanical Polishing)), so that the top limiting areas of the intermediate electrodes 22b* that have been produced such and of the bottom insulation layer 14* are in one and the same plane.

Then (correspondingly similar as with the memory cells illustrated in FIG. 2a), the above-mentioned switching active layer 13* is deposited planarly above the bottom insulation layer 14* and the intermediate electrodes 22b*, and thereabove (also planarly) the material provided for the top electrode layer 12a*, and (again planarly) the hardmask 16* corresponding to the hardmask 16 illustrated in FIG. 2a.

FIG. 2b shows a schematic representation of the memory cells 11 illustrated in FIG. 2a at the next phase during the manufacturing of the memory cells 11.

In the alternative embodiment of the memory cells 11* illustrated in FIG. 4—starting out from the state illustrated in FIG. 4—corresponding process steps are performed as have been explained by means of FIG. 2b (and of FIGS. 2c to 2f) with the memory cells 11. A separate explanation is omitted in the following for the sake of avoiding repetitions.

As results from FIG. 2b, the hardmask 16 positioned above the top electrode layer 12a from which the top electrodes 12a′, 12a″ are manufactured is structured such that it is removed at regions A and is left at corresponding regions B.

For structuring, i.e. here i.a. for the selective removal of the hardmask 16 in the regions A—any conventional methods may be used due to the relatively large dimensions thereof, e.g. opto-lithographic methods (in which the regions A, but not the regions B (or corresponding regions of a photoresist layer provided above the layer 16) are exposed and are then (together with the regions A of the hardmask 16 that are positioned below the corresponding, exposed regions of the photoresist layer) etched away (whereupon the photoresist layer is removed again))

As results from FIG. 2b, a respective region B of the hardmask 16 which is preferably positioned above a bottom electrode 12b (that is assigned to a first, finished individual memory cell 21a (cf. FIG. 3)) is left, and a respective region A that is positioned between bottom electrodes 12b (that are assigned to the second, finished individual memory cell 21b) (cf. FIG. 3)) is removed, etc. The cross-section of the left regions need, of course, not correspond to the cross-section of the bottom electrode 12b; it may have a different shape, be smaller, larger, and/or laterally displaced.

The respectively removed regions A may—viewed from the top—have a substantially square (or rectangular) cross-section.

Corresponding to the representation according to FIG. 2b, further regions—corresponding to the region A—can be removed “in front of” or “behind” the removed region A illustrated in FIG. 2b (and “in front of” or “behind” corresponding removed regions positioned “at the left” and “at the right” of the removed region A) (wherein again a “non-removed” region is positioned between two “removed” regions, and wherein the corners of the removed regions each may be positioned approximately above a corresponding electrode or individual memory cell, respectively).

In a preferred alternative, the left regions B are—viewed from the top—circular or cylinder or ellipse-shaped islands and extend continuously—in the representation according to FIG. 2b—to the “front” or to the “rear” over a plurality of, in particular all, individual memory cells 21a positioned in a row, or over all the electrodes 12b assigned thereto. Linear removed regions A are, however, also possible.

The breadth q of the removed regions A is then distinctly smaller than their length.

Then—as is illustrated schematically in FIG. 2c—the structured hardmask 16′ is etched back isotropically, preferably by a controlled “pull-back” etching. Thus, the lithographic etchmask is reduced (this means in particular that the dimensions of the left regions B are reduced). The resulting sublithographic etchmask is produced in excellent precision by the “pull-back” etching.

By means of the sublithographic etchmask, the layers applied below the sublithographic etchmask can then—as is schematically illustrated in FIGS. 2d to 2f—be structured in the required dimensions, preferably the top electrode layer 12a and/or the switching active material layer 13, but also other layers that are not illustrated here, e.g. further protective layers, insulation layers, etc.

The reduction of the hardmask 16 is in this embodiment performed preferably by isotropic, wet-chemical etching, in particular by H₃PO₄, in particular by hot (e.g. 65° C.) H₃PO₄, especially with a material of the hardmask 16 or of the structured hardmask 16′, respectively, of Si₃N₄ or SiN. For these and other materials of the hardmask 16, 16′ or combinations of the material of the hardmask 16, 16′ and materials of the adjacent layers, here: the electrode material, other etching solutions are also conceivable. H₃PO₄ has the advantage that it etches isotropically, that it etches slowly, and that it does not attack an exposed electrode layer 12a of TiN.

In a variation (not illustrated), the hardmask 16, 16′ may, for instance, also consist of a dielectric two-layer system (e.g. SiN on SiO₂) in which the top layer is used as a sacrifice layer during the “pull-back” step for size reduction while the bottom layer protects the electrode during wet etching and is, for instance, also etched in a dry chemical process for further processing. This corresponds to a process in which the bottom layer corresponds to a protective layer that is removed in a further method step—cf. in particular FIG. 2f—like the hardmask.

FIG. 2d schematically shows the structuring of the layers below the hardmask 16″ that has already been structured and etched back. In this embodiment, both the top electrode layer 12a and the switching active material layer 13 therebelow are structured by etching in correspondence with the sublithographic structure of the hardmask 16. The etching of the layers 12a, 13 positioned below the structured, etched-back hardmask 16″ may, for instance, be performed by dry etching. The structure of the structured, etched-back hardmask 16″ can thus be transferred in analogy to the layers 12b, 13 therebelow. In this embodiment, a sublithographically dimensioned switching active cell 13′ and a corresponding top electrode 12a′ thereabove have been produced. Here, the switching active cell 13′ is thus restricted flatly at the bottom by the bottom electrode 12b and at the top by the top electrode 12a′.

Of course, the sublithographic dimensions of the switching active cell 13′ and/or of the top electrode 12a′ (i.e., for instance, the edge length or the diameter, respectively, in plan view) need not concur exactly.

Of course, no—advantageous—isotropic etching process has to be performed; if required, anisotropic etching may also be performed. Naturally, further layers that are not illustrated in this embodiment may also be available and may be etched correspondingly.

FIG. 2e shows the next step in which a layer 18 of insulating material, e.g. SiO₂, has been applied on the structured surface, said layer 18 been referred to as top insulation layer 18 in the following.

The top insulation layer 18 may have a substantially constant thickness k which corresponds advantageously to at least the sum of the thickness of the top electrode 12a′ and of the switching active element 13′. Preferably, for depositing the top insulation layer 18, a partially planarizing deposition method can—alternatively—be employed, e.g. by utilizing HDP (“high density plasma”) oxide. The thickness k of the insulation layer 18 above the switching active element 13′ is then smaller than in the remaining regions.

Then, the top insulation layer 18 is, as is schematically illustrated in FIG. 2f, removed—preferably planarly—, is preferably polished back. This happens preferably up to roughly the height of the top limiting areas of the top electrodes 12a′ (e.g. by means of an appropriate CMP method (CMP=Chemical Mechanical Polishing)), wherein the remaining structured, etched-back hardmask 16″ is completely removed at least in a partial region. The contacting of the switching active elements 13′ may thus take place from the top via the polished top contacts 12a′.

Finally, as is illustrated in FIG. 3, correspondingly similar as with conventional, known methods for each of the individual memory cells 21a, 21b produced in the above-mentioned manner (and comprising a top and a bottom electrode 12a′, 12b and a switching active element 13′ positioned therebetween and embedded in the top insulation layer 18) a corresponding, top (preferably metal) contact 19a, 19b can be produced which contacts the respective top electrode 12a′ positioned therebelow (cf. FIG. 3).

In a further alternative embodiment—other than illustrated, for instance, in FIGS. 2a and 4—first of all no separate layer that is used for the later production of the electrodes 12a, 12a′ may be provided between the switching active material layer 13, 13′ and the layer 16, 16′ (the switching active material layer 13, 13′ is then directly adjacent to the hardmask 16, 16′, 16″). After performing method steps that correspond to the method steps explained above by means of FIGS. 2a to 2f, the top limiting area of the switching active material layer 13′ produced this way and embedded in an insulation layer 18 is in the same plane as the top limiting area of the top insulation layer 18. Subsequently—correspondingly similar as with corresponding conventional, known production methods—a corresponding (e.g. metal) electrode that contacts the respective, switching active material is manufactured above the switching active material layer for each of the individual memory cells 21a, 21b produced this way.

To achieve, with a corresponding individual memory cell 21a, 21b, a change from an amorphous, i.e. a relatively weakly conductive state of the corresponding “active” material layer 13 to a crystalline, i.e. a relatively strongly conductive state, an appropriate heating current pulse may be applied at the electrodes 12a′, 12b by the respectively assigned, abovementioned switching element (correspondingly similar as with conventional phase change memories, and as explained above with reference to FIG. 1 (cf. also e.g. G. Wicker, Nonvolatile, High Density, High Performance Phase Change Memory, SPIE Conference on Electronics and Structures for MEMS, Vol. 3891, Queensland, 2, 1999, and e.g. Y. N. Hwang et al., Completely CMOS Compatible Phase Change Nonvolatile RAM Using NMOS Cell Transistors, IEEE Proceedings of the Nonvolatile Semiconductor Memory Workshop, Monterey, 91, 2003, S. Lai et al., OUM-a 180 nm nonvolatile memory cell element technology for stand alone and embedded applications, IEDM 2001, etc.)).

The result of the heating current pulse is—since the switching active element 13′ has a relatively high resistance—that it is heated correspondingly beyond the crystallization temperature of the switching active material, whereby a crystallization of the switching active material 13′ may be caused (“writing process”).

Vice versa, a change of state of the switching active element 13′ from a crystalline, i.e. a relatively strongly conductive state to an amorphous, i.e. a relatively weakly conductive state may, for instance, be achieved in that an appropriate heating current pulse is applied at the electrodes 12a′, 12b by means of the respectively assigned, above-mentioned switching element and the switching active element 13′ is thereby heated beyond the melting temperature, and in that the switching active material layer is subsequently “quenched” to an amorphous state by quick cooling (“deleting process”) (correspondingly similar as with conventional phase change memories).

As results from FIG. 3, the switching active element 13′ is embedded into the insulation material layer 18 in the finished state of the memory cells 21a, 21b, is in particular—laterally (towards “the right”, “the left”, “the front” and “the rear”)—completely surrounded by the top insulation layer 18.

FIG. 5 schematically shows a further embodiment of a resistively switching memory cell in a stadium analogous to that of FIG. 2e, wherein the layer available below the structured, etched-back hardmask 16⁺ here was an electrode layer from which an intermediate electrode 22b⁺ was structured out. The intermediate electrode 22b⁺ may be considered as part of the bottom electrode 12b⁺. The material of the bottom insulation layer 14⁺ and of the top insulation layer 18⁺ may be identical, but may also be different. The materials of the intermediate electrode 22b⁺ and of the bottom electrode 12b⁺ need not be identical, either, but may also comprise different insulation material. The current path can also be restricted by the structuring of the intermediate electrode 22b⁺, here: as part of the bottom electrode 12b⁺. In further steps, the insulation layer 18⁺ can be removed in analogy to FIG. 2f. The production steps according to FIGS. 2a-2e and 3 may, for instance, follow then. The sublithographic etching thus may be applied several times during the manufacturing of the memory cell.

FIG. 6 schematically shows a further embodiment of a resistively switching memory cell in a stadium analogous to that of FIG. 2e, wherein, below the structured, etched-back hardmask 16°, a top electrode layer was available, therebelow a switching active layer, and therebelow an electrode layer, which were etched back by dry etching. In the resulting memory cell, the switching active element 13° will thus be completely surrounded by a top electrode 12a° and by an intermediate electrode 22b° (pertaining to the bottom electrode 14⁺) as well as by a top insulation layer 18°. Here, too, the above-described material combinations are possible.

### LIST OF REFERENCE SIGNS

1 memory cell
2a electrode
2b electrode
3 switching active material layer
4 insulation layer
5 heating material layer
11 memory cells
11* memory cells
12a top electrode layer
12a* top electrode layer
12a′ top electrode
12a° top electrode
12b bottom electrode
12b* bottom electrode
12b⁺ bottom electrode
13 switching active layer
13* switching active layer
13′ switching active element
13° switching active element
14 bottom insulation layer
14* bottom insulation layer
14⁺ bottom insulation layer
15 substrate layer
16 hardmask
16* hardmask
16⁺ hardmask
16° hardmask
18 top insulation layer
18⁺ top insulation layer
18° top insulation layer
19a contact
19b contact
21a individual memory cell
21b individual memory cell
22b* intermediate electrode
22b⁺ intermediate electrode
22b° intermediate electrode
A removed regions of the hard mask (16, 16*)
B left regions
e thickness of the intermediate electrode (22b*)
k thickness of the top insulation layer (18)
q breadth of the removed regions (A)

1. A method for manufacturing at least one resistively switching memory cell (11,11*,21a,21b), in particular a phase change memory cell (11,11*,21a,21b), said method comprising at least the steps of:
(a) structuring a hardmask (16, 16*) applied above a further layer (12a,12a*,13,13*);
(b) etching back at least part of the structured hardmask (16′), in particular by isotropic etching.

2. The method according to claim 1, wherein said hardmask (16,16*) is structured substantially in an ellipse shape or in a cylinder shape.

3. The method according to any of claims claim 1, wherein the material of said hardmask (16,16′) comprises at least Si3N4 or SiN.

4. The method according to claim 1, wherein said hardmask (16,16′) consists of a dielectric multi-layer system, in particular of SiN on SiO2.

5. The method according to claim 1, wherein the etching back of the at least part of said structured hardmask (16′) is performed by hot H3PO4, in particular by H3PO4 with a temperature of at least 60° C., especially in a temperature range around 65° C.

6. The method according to claim 1, said method further comprising the step of:
(c) etching back at least one further layer (12a, 12a*, 13,13*) positioned below said structured, etched-back hardmask (16″, 16+, 16°), in particular by dry etching.

7. The method according to claim 6, wherein at least one further layer positioned below said structured, etched-back hardmask (16″,16+,16°) comprises the switching active layer (13,13*) that contains in particular sputtered GST.

8. The method according to claim 6, wherein at least one further layer positioned below said structured, etched-back hardmask (16″,16+,16°) comprises a top electrode layer (12a,12a*) or a bottom electrode layer.

9. The method according to claim 8, wherein step (c) comprises at least one of the partial steps of
(c1) etching back said top electrode layer (12a,12a*) and/or
(c2) etching back said switching active layer (13,13*) and/or
(c3) etching back said bottom electrode layer, in particular for structuring an intermediate electrode (22b+,22b°).

10. The method according to claim 7, said method further comprising the step of:
(d) depositing a top insulation layer (18) of an electrically insulating material, in particular comprising at least SiO2 or SiN, at said structured, etched-back hardmask (16″).

11. The method according to claim 10, wherein the deposition of said top insulation layer (18,18+,18°) is performed such that a switching active element (13′,13°) produced by etching back of said switching active layer (13,13*) is completely embedded laterally into said top insulation layer (18,18+,18°).

12. The method according to claim 10, said method further comprising the step of:
(e) flat removal, in particular by a CMP method, of the surface comprising said top insulation layer (18,18+,18°) such that said switching active element (13′,13°) is contactable.

13. A memory cell (11,11*) manufactured with the method according to claim 1.

14. The memory cell (11,11*) according to claim 13, comprising:
at least one switching active element (13′,13°), contacted by at least
one top electrode (12a′,12a°) adjacent to said switching active element (13′) and
one bottom electrode (12b,22b′,22b+,22b°) adjacent to said switching active element (13′,13°) at some other position.

15. The memory cell (11,11*) according to claim 13, wherein the material of at least one electrode (12a′,12a°,12b,12b*,22b+,22b°) comprises a titanium compound, in particular TiN or TaN, or TaSiN or tungsten.

16. The memory cell (11,11*) according to claim 15, wherein one electrode (12a′,12a°,12b,12b*,22b+,22b°) comprises TiN and the other, corresponding electrode (12a′,12a°,12b,12b*,22b+,22b°) comprises tungsten.

17. The memory cell (11,11*) according to claim 14, wherein said switching active element (13′,13°) is completely surrounded by said first electrode (12a′,12a°,12b, 12b*,22b+,22b°) and said corresponding second electrode (12a′,12a°,12b,12b*,22b+,22b°) and by said top insulation layer (18,18+,18°).

18. The memory cell (11,11*) according to claim 13, wherein said switching active element (13′,13°) contains sputtered GST.

19. A memory device (21a) comprising at least one memory cell (11,11*) according to claim 13, in particular with at least one additional contacting (19a,19b) to said top electrode (12a′,12a°).
